(19) United States
(12) Patent Application Publication
(10) Pub. No.: US 2014/0332811 A1
(43) Pub. Date: Nov. 13, 2014

(54) SEMICONDUCTOR DEVICE WITH BOND AND PROBE PADS

(71) Applicants: Naveen Kumar, Jhajjar (IN); Gurinder Singh Baghria, Ludhiana (IN); Rishi Bhooshan, Ghaziabad (IN); Jesse Phou, Austin, TX (US)

(72) Inventors: Naveen Kumar, Jhajjar (IN); Gurinder Singh Baghria, Ludhiana (IN); Rishi Bhooshan, Ghaziabad (IN); Jesse Phou, Austin, TX (US)

(21) Appl. No.: 13/892,297

(22) Filed: May 12, 2013

(51) Int. Cl. H01L 21/66

(52) U.S. Cl. CPC H01L 22/32
USPC 257/48

(57) ABSTRACT

A semiconductor die has an active face with an arrangement of I/O pads around its edges. The I/O pads include bond pads and probe pads. Two types of I/O pads are provided and the two types of pads are arranged in a staggered arrangement around the edges of the die. The first type of I/O pad has bond pads that are spaced from the probe pads and connected with an interconnecting member. The second type of I/O pads has bond pads that are adjacent to and abutting probe pads. Providing two types of I/O pads and the staggered arrangement of the I/O pads reduces the area of the I/O pads and underlying I/O regions, which saves core area of the die.

### BACKGROUND OF THE INVENTION

The present invention is directed to semiconductor dies and, more particularly, to the arrangement of bond and probe pads on semiconductor dies.

A semiconductor die has Input/Output (I/O) pads on its active surface that allow for external electrical connections. In a wire bonded package, a semiconductor die may be mounted on a support (e.g., a lead frame flag) with peripheral I/O pads on the active face of the die opposite from the lead frame support. Bond wires are then bonded to the die I/O pads and to electrical contacts of the package (e.g., lead fingers of the lead frame). The die I/O pads electrically connect with underlying input/output (I/O) regions of the die integrated circuits.

The semiconductor die I/O pads also typically include probe pads associated with the contact pads on the active face of the die. The probe pads facilitate testing of the die during manufacturing by a probe test machine that has mechanical probes that contact the probe pads. Thus, a die I/O pad includes a bond pad and a probe pad. Such dual pads commonly have distinct areas for bonding and probing, to avoid the quality of the wire bonding operations being compromised by damage to the pads during previous probe operations.

As technology nodes are shrinking, the I/O pads widths also are decreasing, which is making the bond and probe pitch requirements quite a challenge to meet. The decrease in I/O pad width may require extra spacers between two bond/probe pads to meet the bond and probe pitch requirements, which results in increase of die area and hence die cost. Thus, staggered bonding/probing architecture has become a popular in lower technologies to save the die area.

FIG. 1 illustrates a portion of an active face of a conventional semiconductor die 100. The die 100 has I/O pads 102 that are located along an edge 104 of the die 100. Each of the I/O pads 102 includes a bond pad 106, a probe pad 108, and a metal interconnect 110 that connects the bond pad 106 to its associated probe pad 108. That is, for each I/O pad 102, the bond pad 106 is spaced or separated from the probe pad 108, which allows the I/O pads 102 to be staggered around the die edge 104. The I/O pads 102 are arranged such that the bond pads 106 overlie an I/O circuit 112 of the die 100.

The I/O circuit 112 extends from the die edge 104 towards the center of the semiconductor die 100. Note that the spaced layout of the bond and probe pads 106 and 108 and the staggered arrangement of the I/O pads 102 causes the probe pads 108 to extend into a core area of the die 100, beyond the I/O regions 112, which restricts utilization of the core area underneath the probe pads 108 that can be used for gates. Furthermore, the probe pads 108 may utilize three or more top metal layers within the core area, which makes these metal layers unavailable for routing gates therebeneath. Additionally, the metal interconnects 110 comprise thin metal strips that may have an undesirably high electrical resistance.

It would be desirable to have an I/O pad arrangement that does not exceedingly infringe on the core area of the die, making for more efficient use of the die area.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. In particular the sizes of contact pads and connectors have been exaggerated relative to the overall size of a typical semiconductor die.

FIG. 1 is a top plan view of a portion of an active face of a semiconductor die having a known bond and probe pad arrangement;

FIG. 2 is a top plan view of a portion of an active face of a semiconductor die having a bond and probe pad arrangement in accordance with an embodiment of the present invention;

FIG. 3 is a top plan view of a portion of an active face of a semiconductor die having a bond and probe pad arrangement in accordance with another embodiment of the present invention;

FIG. 4 is a top plan view of an active face of the semiconductor die having a bond and probe pad arrangement as shown in FIG. 2; and

FIG. 5 is a top plan view of an active face of the semiconductor die having a bond and probe pad arrangement as shown in FIG. 3.

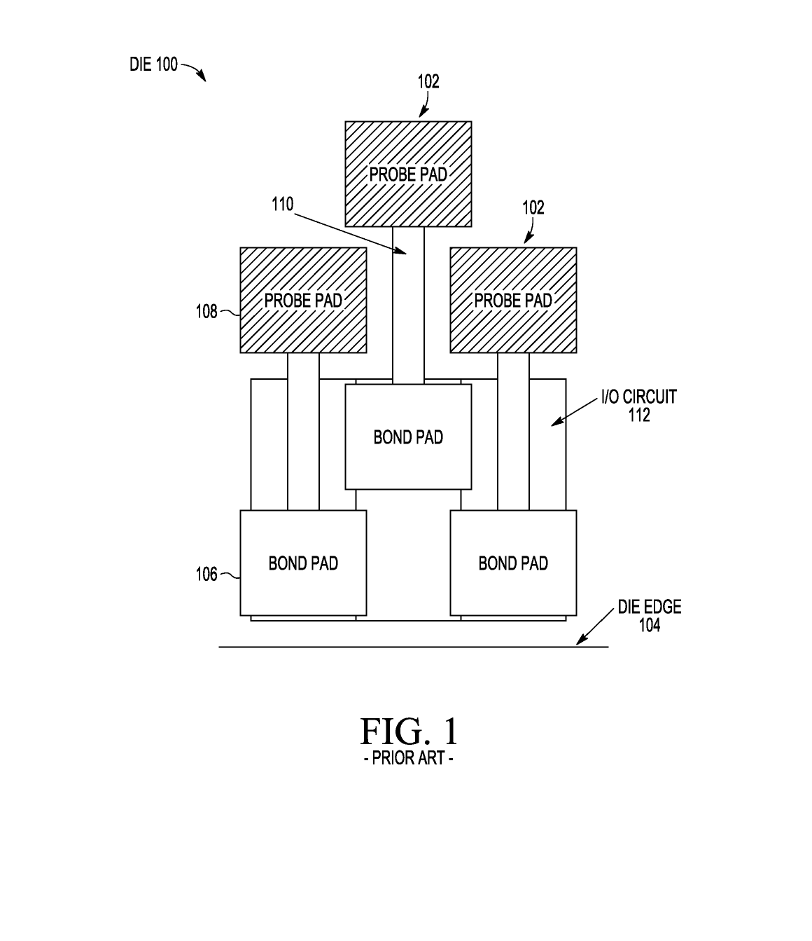

### DETAILED DESCRIPTION OF THE INVENTION

In one embodiment, the present invention provides a semiconductor device having external contact elements for connection to external electrical circuits, and a semiconductor die having an active face including first and second types of input/output (I/O) pads arranged along edges of the die. The first type of I/O pads comprises a bond pad, a probe pad spaced from the bond pad, and an interconnect member connecting the bond pad with the probe pad. The second type of I/O pads comprises a bond pad and a probe pad adjacent to and abutting the bond pad. The first and second types of I/O pads are staggered in an alternating arrangement around the edges of the die such that the bond pads of the first type of I/O pads form a first row of pads adjacent to the die edges, the probe pads of the first type of I/O pads form a second row of pads spaced from the edges of the die, and the second type of I/O pads form an intermediate row of pads. An I/O region underlies at least two of the rows and is connected electrically with the first and second types of I/O pads.

The bond pads of the first and second types of I/O pads are electrically connected to the external contact elements, and the probe pads of the first and second types of I/O pads are for contact by a mechanical probe during manufacture and testing of the semiconductor device.

In one embodiment, the probe pads of the second type of I/O pads are located closer to the second row than the bond pads of the second type of I/O pads. In another embodiment, the bond pads of the second type of I/O pads are located closer to the second row than the probe pads of the second type of I/O pads.

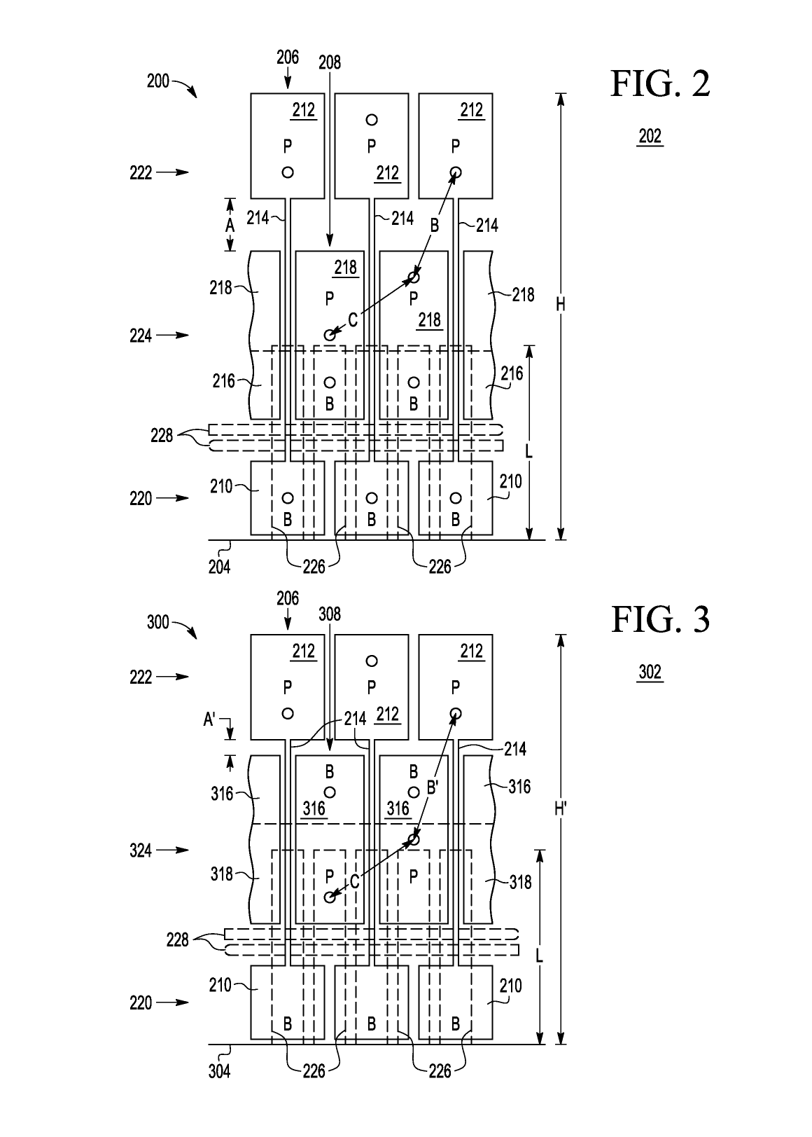

Referring now to FIG. 2, a top plan view of a portion of a semiconductor die 200 having an active face 202 is shown. The semiconductor die 200 has a bond and probe pad arrangement on its active face 202 in accordance with an embodiment of the present invention. The bond and probe pads, as discussed in more detail below, are located along or around the outer edges 204 (one is shown) of the die 200.

According to the present invention, first and second first and second types of input/output (I/O) pads 204 and 206 are arranged along the die edges 204. The first type of I/O pads 206 comprise a bond pad 210, a probe pad 212 spaced from the bond pad 210, and an interconnect member 214 connecting the bond pad 210 with the probe pad 212. The second type of I/O pads 208 (also referred to herein as dual bond and probe pads) comprise a bond area 216 and a probe area 218 adjacent to and abutting the bond area 216. In the drawings, bond areas or bond pads are denoted with a B, while probe pads or probe areas are denoted with a P. Also in the drawings, the bond areas B 216 and probe areas P 218 of the dual pads 208 are shown separated by a dashed line.

As can be seen in FIG. 2, the first and second types of I/O pads 206 and 208 are staggered in an alternating arrangement around the edges 204 of the die 200 such that the bond pads 210 of the first type of I/O pads 206 form a first row 220 of pads adjacent to the die edges 204, the probe pads 212 of the first type of I/O pads 206 form a second row 222 of pads spaced from the edges 204 of the die 200, and the second type of I/O pads 208 form an intermediate row 224 of pads. Since the first type of I/O pads have bond pads 210 spaced from the probe pads 212, the second type of I/O pads 208 are located between the bond pads 210 and the probe pads 212. The die 200 includes I/O regions 226 underlying at least two of the rows and connected electrically with the first and second types of I/O pads 206 and 208.

As will be understood by those of skill in the art, the bond pads 210 and the bond areas 216 are connected to external contact elements, typically with bond wires (not shown), where a bond wire is attached to the bond pad 210 or the bond area 216 with a ball bond and to the external contact element with a stitch bond by a wire bonding machine. On the other hand, the probe pads 212 and the probe areas 218 are for contact by a mechanical probe during manufacture and testing of the semiconductor die.

In the embodiment shown in FIG. 2, the probe areas 218 of the second type of I/O pads 208 are located closer to the second row 222 than the bond areas 216 of the second type of I/O pads 208. In addition, there are voltage and ground power supply rails 214 under the active face 202 of the semiconductor die 200 that impose an spacing limitations (discussed in more detail below) between the rows 220 and 224.

Manufacturing considerations impose minimum sizes of the bond pads B 210, bond areas B 216, probe pads P 212 and probe areas P 218. In FIG. 2, circles indicate target sites for the bond wire in each of the bond pads 210 and bond areas 216, and target sites for the probe contact in each of the probe pads 212 and probe areas 218. Manufacturing tolerances and risk of unwanted contact or damage to adjacent areas impose minimum spacing limitations between the target bond sites of the adjacent bond pads 210 and bond areas 216. And as mentioned above, in this example, voltage and ground power supply rails 214 under the active face of the semiconductor die 202 impose an additional spacing between the rows 206 and 210. Minimum pitches between adjacent probes of the probe test machine impose minimum pitches between the target probe sites of adjacent probe pads 212 and probe areas 218, and therefore minimum spacing between adjacent probe pads 212 and probe areas 218, as indicated by the arrows A, B and C.

The I/O regions 226 extend a distance L towards the center of the die 200 from the adjacent edge 204 and limit the sea of gates area available for placing functional electrical circuits in the die 200. The intermediate row 224 of dual pads 208 and the second row 222 of probe pads 212 extend further into the sea of gates area and limit the signal routing resources underneath, especially since in this example the pads 206 and 208 have three top layers of metal (aluminum pad top layer and two copper layers next below) for enhanced reliability of bonding and probing operations. This reduces the number and average density of functional circuit elements in the die 200, whose power supply rails have to be ensured by metal layers below the top three metal layers. However, the encroachment of probe pads 212 and probe areas 218 of the dual pads 208 into the sea of gates area can be less than in the conventional semiconductor die 100, since the dual pads 208 occupy less area than the interleaved arrangement of I/O pads 106, 108 of the conventional die 100. In one example of a die 200, the overall distance H that the rows 220, 222 and 224 extend from the edge 204 of the semiconductor die 200 is 389.4 μm (in layout dimensions) and the additional distance (H-L) that they extend over the sea of gates area beyond the I/O regions 212 is 215.4 μm.

The bond pads 210 of the first row 220 and the dual pads 208 of the intermediate row 224 connect directly with the I/O regions 226 underneath. However, the probe pads 212 of the second row 222 are connected to respective bond pads 210 of the first row 220 with the interconnecting members 214, which provide an indirect connection with the I/O regions 226 since the probe pads 212 are not positioned over the I/O regions 226. The interconnecting members 214 are narrow (2 μm in this example) because they pass between adjacent ones of the dual pads 208 of the intermediate row 224. Their mutual inductance and mutual capacitance with adjacent elements can be less than in the conventional die 100. However, the longer the members 214 are, the greater their resistance and the greater the voltage drop along their length during the probing operation. It is desirable to reduce the overall distance H in order to decrease the length of the interconnecting members 214 and to reduce encroaching into the core area of the die 200.

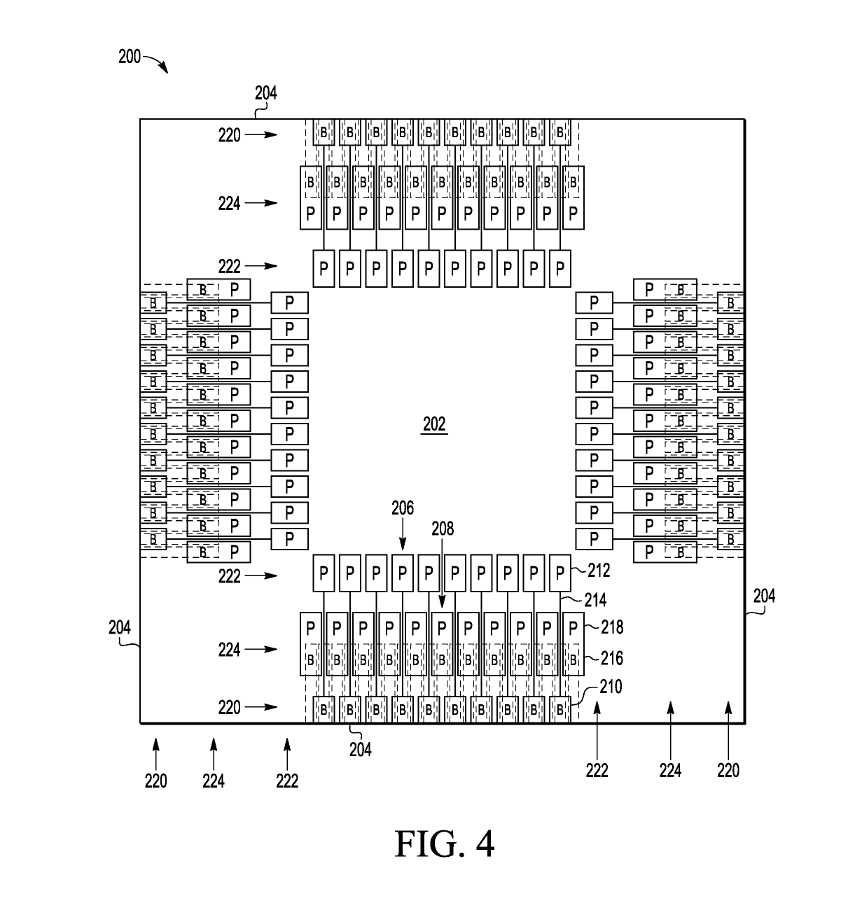

FIG. 4 shows the active face 202 of the semiconductor die 200 with an arrangement of first and second types of I/O pads 206 and 208 interleaved around the edges 204 of the die 200.

FIG. 3 illustrates a semiconductor die 300 in accordance with an example of an embodiment of the present invention. The semiconductor die 300 is similar to the die 200 shown in FIG. 2 so like elements are indicated with like numbers. The principle difference between the die 200 and the die 300 is that a second type of I/O pads 308 are placed such that a bond area 316 is close to the probe pads 212 of the first type of I/O pads 206 and a probe area 318 is close to the bond pad 210 of the first type of I/O pads 206. Put another way, the bond areas 316 are located closer to the second row 222 than the probe areas 318.

The minimum spacing A′ between adjacent probe pads 212 of the second row 222 and bond areas 316 of the intermediate row 324 of the semiconductor die 300 is considerably less than the minimum spacing A between adjacent probe pads 212 of the second row 222 and probe areas 218 of the intermediate row 224 of the semiconductor die 200. Nonetheless, the pitch B′ of the target probe sites in the probe pads 212 of the second row 222 closest to the target probe sites in probe areas 318 of the dual pads 308 of the intermediate row 324 is greater than the pitch B in the semiconductor die 200 and greater than the minimum specified. In an example of the semiconductor die 300 whose dimensions are otherwise similar to the semiconductor die 200, the spacing A′ is 4.5 μm, compared to a value of 37.4 μm for the spacing A, the overall distance H′ that the rows 220, 222 and 324 extend from the edge 304 of the semiconductor die 300 is 356.5 μm, compared to a value of 389.4 μm for the distance H, and the additional distance (H-L) that the rows 220, 222 and 324 extend over the sea of gates area beyond the I/O regions 226 is 182.5 μm, compared to 215.4 μm in the semiconductor die 200. The sea of gates area gained is available for routing connections in the metal layers below the top aluminum pad layer and for placement of additional functional circuit elements, or alternatively for reducing the size of the die 300 for the same complexity of circuit elements.

In one example of manufacture and testing of the semiconductor die 300, an operation of probe testing using the probe areas 318 of the dual bond and probe pads 308 is performed at the wafer stage, before bond wires are attached to the bond areas 316 of the dual pads 308. Probe testing after singulation, bond wire attachment and packaging may be performed by probing the probe areas 318 and the probe pads 212.

The interconnection members 214 of the semiconductor die 300 may be shorter than the connectors 214 of the semiconductor die 200 due to the reduction in the overall distance H′ compared to the value H of the semiconductor die 200, reducing their electrical resistance; with the dimensions mentioned above, the reduction in resistance of the connection members 214 of the semiconductor die 300 compared to the length of the connection members 214 of the die 200 is about 18%. The I/O regions 226 may be closer to the edge 304 than the second row is to the edge, although it is also possible to position the I/O regions 226 closer to the center of the semiconductor die 300, within the distance H′.

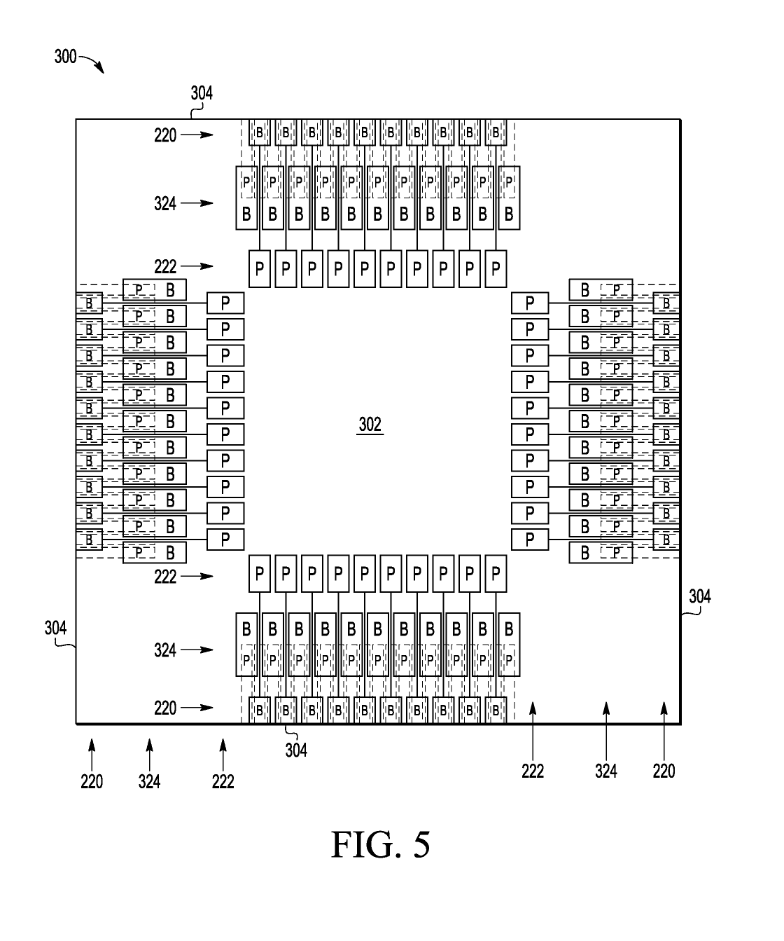

FIG. 5 shows the active face 302 of the semiconductor die 300 with an arrangement of first and second types of I/O pads 206 and 308 interleaved around the edges 304 of the die 300.

In the foregoing specification, the invention has been described with reference to specific examples of embodiments of the invention. It will, however, be evident that various modifications and changes may be made therein without departing from the broader spirit and scope of the invention as set forth in the appended claims.

For example, a semiconductor device may be assembled that has more than one die. Also, the semiconductor dies 200 and 300 are shown and described as having three straight rows 220, 222, and 224/324 of electrical contact pads but it will be appreciated that more than three rows of contact pads may be provided and one or more of the rows of contact pads may be staggered instead of straight. The semiconductor dies described herein can be made from any semiconductor material or combinations of materials, such as gallium arsenide, silicon germanium, silicon-on-insulator (SOI), silicon, monocrystalline silicon, the like, and combinations of the above.

Terms like “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice-versa. Also, a plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

In the claims, the word ‘comprising’ or ‘having’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A semiconductor device, comprising:
external contact elements for connection to external electrical circuits; and
a semiconductor die having outer edges and an active face including first and second types of input/output (I/O) pads arranged along the die edges,
wherein the first type of I/O pads comprise a bond pad, a probe pad spaced from the bond pad, and an interconnect member connecting the bond pad with the probe pad,
wherein the second type of I/O pads comprise a bond area and a probe area adjacent to and abutting the bond area,
wherein the first and second types of I/O pads are staggered in an alternating arrangement around the edges of the die such that the bond pads of the first type of I/O pads form a first row of pads adjacent to the die edges, the probe pads of the first type of I/O pads form a second row of pads spaced from the edges of the die, and the second type of I/O pads form an intermediate row of pads, and
wherein there is an I/O region underlying at least two of the rows and connected electrically with the first and second types of I/O pads.

2. The semiconductor device of claim 1, wherein the bond pads of the first type of I/O pads and the bond areas of the second type of I/O pads are electrically connected to respective ones of the external contact elements, and the probe pads of the first type of I/O pads and the probe areas of the second type of I/O pads are for contact by a mechanical probe during manufacture and testing of the semiconductor device.

3. The semiconductor device of claim 2, wherein the probe areas of the second type of I/O pads are located closer to the second row than the bond areas of the second type of I/O pads.

4. The semiconductor device of claim 2, wherein the bond areas of the second type of I/O pads are located closer to the second row than the probe areas of the second type of I/O pads.

5. The semiconductor device of claim 2, wherein the bond pads of the first row and the bond and probe areas of the intermediate row overlay and are connected with the I/O regions.

6. The semiconductor device of claim 2, wherein the I/O regions are closer to the die edge than the second row is to the edge.

7. A semiconductor die for use in making a semiconductor device that has external contact elements for connection to external electrical circuits, the semiconductor die comprising:
an active face bounded by edges and including a first row of bond pads for connection to a first set of the external contact elements, a second row of probe pads for contact by mechanical probes during manufacture and testing of the semiconductor die, interconnecting members connecting the first row of bond pads with the second row of probe pads, an intermediate row of dual bond and probe pads, and input/output (I/O) regions underlying at least two of the rows and connected electrically with the bond pads, probe pads and dual bond and probe pads;
wherein each of the dual bond and probe pads has a bond area for connection to an external contact element of a second set of the external contact elements, and a probe area adjacent to and abutting the bond area, the probe area for contact by a mechanical probe during manufacture and testing of the semiconductor die; and
wherein the bond and probe pads of the first and second rows are in an alternating arrangement with the dual bond and probe pads of the intermediate row.

8. The semiconductor die of claim 7, wherein the first row is closer to an edge of the semiconductor die than the intermediate row and the second row are to the edge.

9. The semiconductor die of claim 8, wherein the probe areas of the dual bond and probe pads are located closer to the second row than the bond areas are to the second row.

10. The semiconductor die of claim 8, wherein the bond areas of the dual bond and probe pads are located closer to the second row than the probe areas are to the second row.

11. The semiconductor die of claim 10, wherein the bond pads of the first row and the dual bond and probe pads of the intermediate row overlay and are connected with the I/O regions.

12. The semiconductor die of claim 8, further comprising interconnecting members on the die active face connecting the bond pads of the first row with respective probe pads of the second row.

13. The semiconductor die of claim 12, wherein the I/O regions are closer to the edge than the second row is to the edge.
